(19) United States
(12) Patent Application Publication
(10) Pub. No.: US 2023/0014007 A1
(43) Pub. Date: Jan. 19, 2023

(54) METHOD OF MANUFACTURING SEMICONDUCTOR STRUCTURE AND SEMICONDUCTOR DEVICE ETCHING EQUIPMENT

(71) Applicant: CHANGXIN MEMORY TECHNOLOGIES, INC., Hefei City (CN)

(72) Inventors: Xifei BAO, Hefei City (CN); Liutao ZHOU, Hefei City (CN)

(21) Appl. No.: 17/451,671

(22) Filed: Oct. 21, 2021

Related U.S. Application Data
(63) Continuation of application No. PCT/CN2021/109244, filed on Jul. 29, 2021.

(30) Foreign Application Priority Data
Jul. 16, 2021 (CN) 202110805469.2

(51) Int. Cl. H01L 21/311; H01L 21/67

(52) U.S. Cl. CPC H01L 21/31138; H01L 21/31116; H01L 21/67069; H01L 21/67023

(57) ABSTRACT

The present disclosure provides a method of manufacturing a semiconductor structure and a semiconductor device etching equipment. The semiconductor structure manufacturing method includes: providing a semiconductor structure to be processed, putting the semiconductor structure to be processed in a processing chamber, wherein the semiconductor structure to be processed includes a substrate and target structures to be processed located on the substrate, and sidewalls of the target structures to be processed are covered with bromine-containing polymer layers; removing the bromine-containing polymer layers, and forming a semiconductor structure; and removing products resulting from a process of removing the bromine-containing polymer layers from the processing chamber.

### CROSS-REFERENCE TO RELATED APPLICATIONS

This is a continuation of International Application No. PCT/CN2021/109244, filed on Jul. 29, 2021, which claims the priority of Chinese Patent Application No. 202110805469.2, filed with the CNIPA on Jul. 16, 2021, and titled “METHOD OF MANUFACTURING SEMICONDUCTOR STRUCTURE AND SEMICONDUCTOR DEVICE ETCHING EQUIPMENT”.

The entire contents of International Application No. PCT/CN2021/109244 and Chinese Patent Application No. 202110805469.2 are incorporated herein by reference.

### TECHNICAL FIELD

The present disclosure relates to, but is not limited to, a method of manufacturing a semiconductor structure and a semiconductor device etching equipment.

### BACKGROUND

Residual gas is easily produced on a surface of a silicon wafer etched in an etching chamber, and will easily bond and react with the gas containing molecular air contaminants in the atmosphere, and condensation in the reaction process will have adverse effects on the surface of the silicon wafer.

For example, hydrogen bromide (HBr) often serves as a main etchant in a semiconductor device. During etching, bromine-containing polymer layers may be formed on sidewalls of polysilicon. After etching, HBr remaining on the surface of the wafer will be condensed with the water in the etching chamber to produce strong acid, and the strong acid will adhere to the surfaces of the semiconductor device to easily cause defects of HBr concentration, thus affecting the yield of semiconductor devices.

In the related technologies, the sources of contamination entering the etching chamber are reduced by providing an air filter, or gases such as HBr are diluted by introducing protective gas (such as nitrogen) into the etching chamber and pumped out by a vacuum pump, so as to reduce the probability of condensation. However, the bromine-containing polymer is unstable and easily regenerates HBr in the etching chamber, thus affecting the yield of semiconductor devices.

### SUMMARY

The following is a summary of subject matters described in detail herein, which is not intended to limit the protection scope defined by the claims.

The present disclosure provides a method of manufacturing a semiconductor structure and a semiconductor device etching equipment.

According to a first aspect of the present disclosure, a method of manufacturing a semiconductor structure is provided, comprising: providing a semiconductor structure to be processed, putting the semiconductor structure to be processed in a processing chamber, wherein the semiconductor structure to be processed comprises a substrate and target structures to be processed located on the substrate, and sidewalls of the target structures to be processed are covered with bromine-containing polymer layers; removing the bromine-containing polymer layers, and forming a semiconductor structure; and removing products resulting from a process of removing the bromine-containing polymer layers from the processing chamber.

According to a second aspect of the present disclosure, a semiconductor device etching equipment is provided, for implementing the method of manufacturing a semiconductor structure described in the technical solution according to the first aspect, comprising: at least one processing chamber, configured to hold a semiconductor structure to be processed; at least one processing device, configured to remove bromine-containing polymer layers; and at least one cleaning device, configured to be communicated with the processing chamber, and clean products resulting from a process of removing the bromine-containing polymer layers.

Other aspects will become apparent after reading and understanding the drawings and detailed description.

### BRIEF DESCRIPTION OF THE DRAWINGS

The drawings, which are incorporated in and constitute a part of the specification, illustrate embodiments of the present application and, together with the description, serve to explain the principles of the embodiments of the present disclosure. In these drawings, similar elements are denoted by similar reference numerals. The drawings in the following description are some, but not all, of the embodiments of the present disclosure. Those of skill in the art may obtain other drawings based on these drawings without paying any creative efforts.

Exemplary description may be made to one or more embodiments with reference to the corresponding drawings without limiting these embodiments. Elements denoted by the identical reference numerals in the drawings are similar elements, and the drawings are not drawn to scale unless otherwise stated.

FIG. 1 is a flowchart of a method of manufacturing a semiconductor structure according to an exemplary embodiment;

FIG. 2 is a flowchart of a method of manufacturing a semiconductor structure according to an exemplary embodiment;

FIG. 3 is a flowchart of a method of manufacturing a semiconductor structure according to an exemplary embodiment;

FIG. 4 is a flowchart of a method of manufacturing a semiconductor structure according to an exemplary embodiment;

FIG. 5 is a flowchart of a method of manufacturing a semiconductor structure according to an exemplary embodiment;

FIG. 6 is a flowchart of a method of manufacturing a semiconductor structure according to an exemplary embodiment;

FIG. 7 is a schematic diagram of a semiconductor structure obtained after performing S202 according to the exemplary embodiment;

FIG. 8 is a schematic diagram of a semiconductor structure obtained after performing S302 according to the exemplary embodiment;

FIG. 9 is a schematic diagram of a semiconductor structure obtained after performing S303 according to the exemplary embodiment;

FIG. 10 is a schematic diagram of a semiconductor structure obtained after performing S304 according to the exemplary embodiment;

FIG. 11 is a schematic diagram of a semiconductor structure obtained after performing S102 of the method of manufacturing a semiconductor structure according to the exemplary embodiment;

FIG. 12 shows a structural diagram of a semiconductor device etching equipment provided according to some exemplary embodiments of the present disclosure;

FIG. 13 shows a structural diagram of a second storage chamber and a protective gas storage device provided according to some exemplary embodiments of the present disclosure;

FIG. 14 is a flowchart of a semiconductor structure etching process according to some exemplary embodiments of the present disclosure;

FIG. 15 is a schematic diagram showing changes in the relative humidity in a processing chamber according to some exemplary embodiments of the present disclosure; and

FIG. 16 is a schematic diagram showing changes in the concentration of hydrogen bromide in the processing chamber according to some exemplary embodiments of the present disclosure;

in which:

100: substrate; 200: target structure to be processed; 210: bromine-containing polymer layer; 211: silicon oxide layer; 300: mask layer;

10: processing chamber; 20: transfer chamber; 30: buffer chamber; 40: first storage chamber;

50: second storage chamber;

60: protective gas storage device; 61: gas delivery pipe; 611: purification pipe; 612: manual valve; 613: pressure gage; 614: pneumatic valve; 615: gas flow controller; 62: gas return pipe; 70: first robot arm; and 80: second robot arm.

### DETAILED DESCRIPTION

In order to make the objectives, technical solutions and advantages of the embodiments of the present disclosure clearer, the technical solutions in the embodiments of the present disclosure will be described clearly and completely with reference to the drawings in the embodiments of the present disclosure. Obviously, the described embodiments are merely a part of, not all of, the embodiments of the present disclosure. Based on the embodiments in the present disclosure, all other embodiments obtained by those of skill in the art without paying any creative efforts shall fall into the protection scope of the present disclosure. It should be noted that the embodiments and features therein of the present disclosure may be randomly combined with each other without conflict.

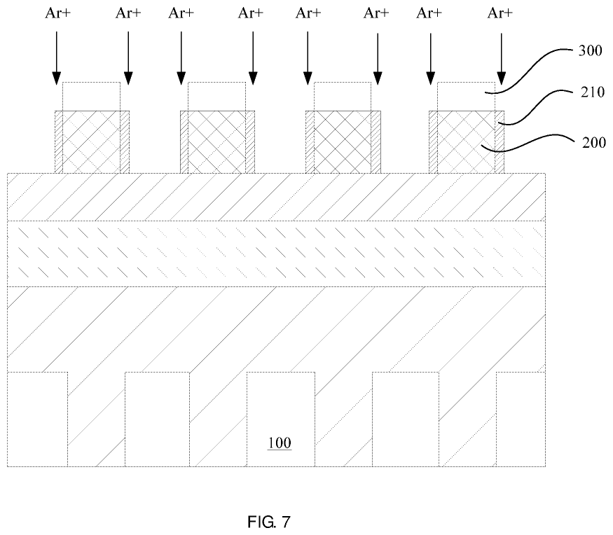

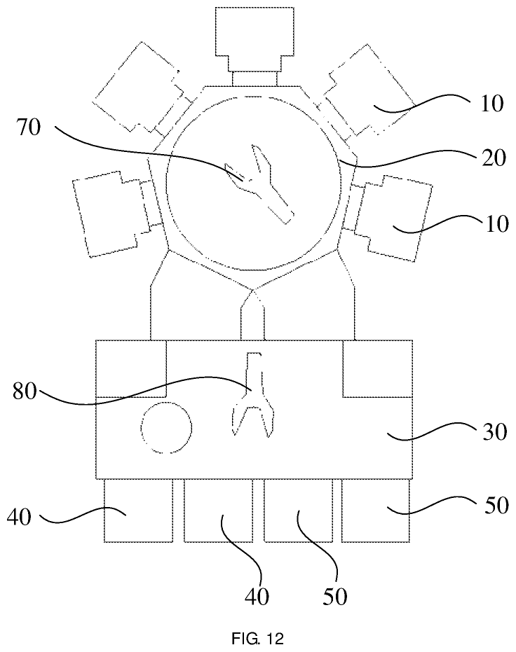

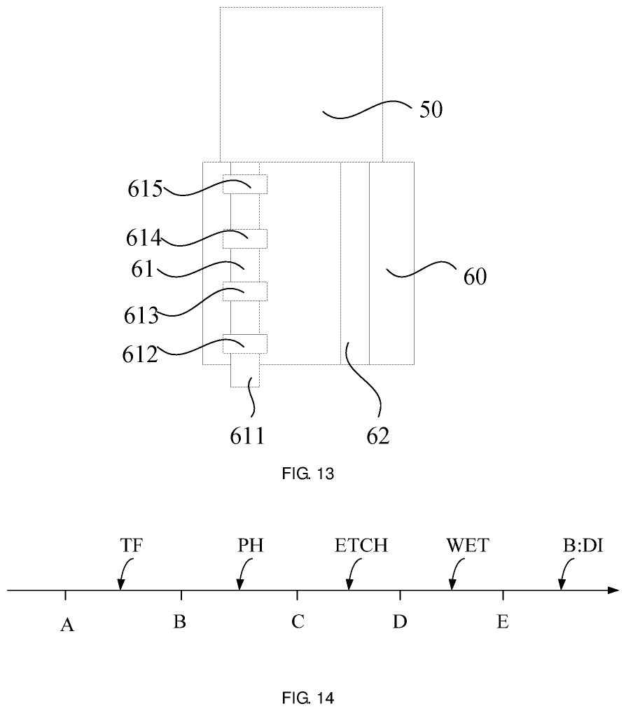

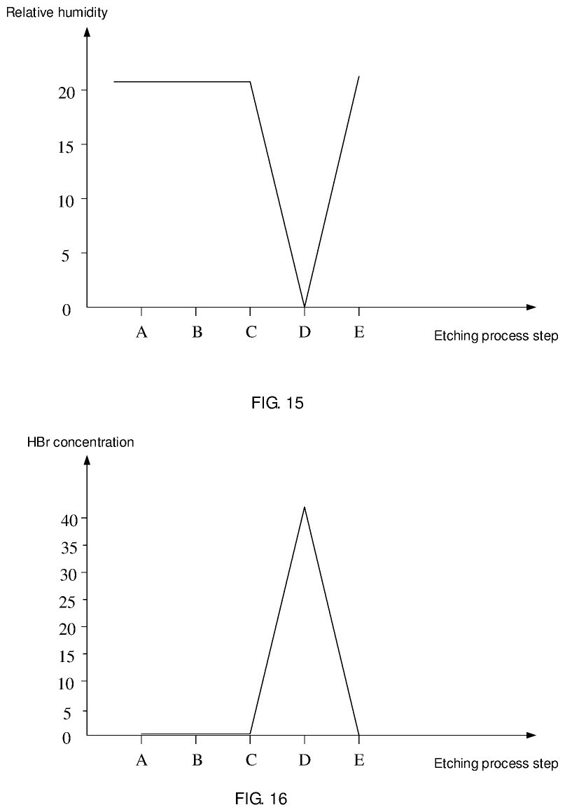

According to exemplary embodiments of the present disclosure, a method of manufacturing a semiconductor structure is provided. FIGS. 1 to 6 show flowcharts of the method of manufacturing a semiconductor structure provided according to some exemplary embodiments of the present disclosure, FIGS. 7 to 11 show schematic diagrams of various stages of the method of manufacturing a semiconductor structure, and FIGS. 12 and 13 show structural diagrams of a semiconductor device etching equipment provided according to some exemplary embodiments of the present disclosure. FIG. 14 is a flowchart of a semiconductor structure etching process according to some exemplary embodiments of the present disclosure; FIG. 15 is a schematic diagram showing changes in the relative humidity in a processing chamber according to some exemplary embodiments of the present disclosure; FIG. 16 is a schematic diagram showing changes in the concentration of hydrogen bromide in the processing chamber according to some exemplary embodiments of the present disclosure.

The method of manufacturing a semiconductor structure will be described with reference to FIGS. 1 to 6.

In this embodiment, semiconductor structures are not limited, and a semiconductor structure will be described below as a Dynamic Random Access Memory (DRAM), which is not limited but may also be other structures in this embodiment.

As shown in FIG. 1, a method of manufacturing a semiconductor structure provided according to an exemplary embodiment of the present disclosure comprises S101 to S103.

In the S101, a semiconductor structure to be processed is provided and put the semiconductor structure to be processed in a processing chamber. The semiconductor structure to be processed comprises a substrate and target structures to be processed located on the substrate, and sidewalls of the target structures to be processed are covered with bromine-containing polymer layers.

In the S102, the bromine-containing polymer layers are removed, and form a semiconductor structure.

In the S103, products resulting from the process of removing the bromine-containing polymer layers are removed from processing chamber.

In the S101, as shown in FIG. 7, there are a plurality of target structures to be processed 200 on the substrate 100, and a groove, which is specifically obtained by an etching process, is provided between every two adjacent target structures to be processed 200 to make each target structure to be processed 200 have the sidewalls. After the grooves are etched, etching gas and contamination gas in an etching chamber form the bromine-containing polymer layers 210 on the sidewalls of the target structures to be processed 200, and the bromine-containing polymer layers 210 comprise bromine-containing silicon oxide (SiₓO_{y}Br_{z}) and hydrocarbon oxide (CₓH_{y}O_{z}). It should be noted that a mask layer 300, mainly configured to protect the targets to be processed and define positions of the grooves, is also covered above the target structures to be processed 200.

The semiconductor structure to be processed is a Dynamic Random Access Memory (DRAM), which comprises a substrate 100 and target structures to be processed 200 located on the substrate 100, and each target structure to be processed 200 is of a Landing Pad structure to be connected to a bottom electrode of a capacitor in the DRAM. Bit lines, word lines, gate structures, source regions, drain regions, conductor layers, dielectric layers and other structures (not shown) may be disposed on the substrate 100. The semiconductor structure may also be other semiconductor devices.

In the S102, as shown in FIG. 11, the bromine-containing polymer layers 210 are removed, and form products and a semiconductor structure. The difference between the semiconductor structure and the semiconductor structure to be processed is that the bromine-containing polymers on the target structures to be processed 200 are removed, thereby removing bromine-containing substances from the semiconductor structure.

In the S103, since the bromine-containing polymers will easily react with water vapor in the processing chamber to regenerate hydrogen bromide (HBr), the HBr is condensed with the water in the etching chamber to produce strong acid, and the strong acid will adhere to the surfaces of the semiconductor device to easily cause defects of the semiconductor device. Therefore, in this step, the products resulting from the process of removing the bromine-containing polymer layers 210 are removed from the processing chamber to avoid the bromine-containing polymers from generating HBr in the processing chamber, so that bromine is removed from the processing chamber more completely, the probability of HBr condensation on the semiconductor structure is reduced, and the yield of the semiconductor structures is improved. In an exemplary embodiment, the products are pumped out of the processing chamber by a vacuum pump, thereby achieving bromine removal.

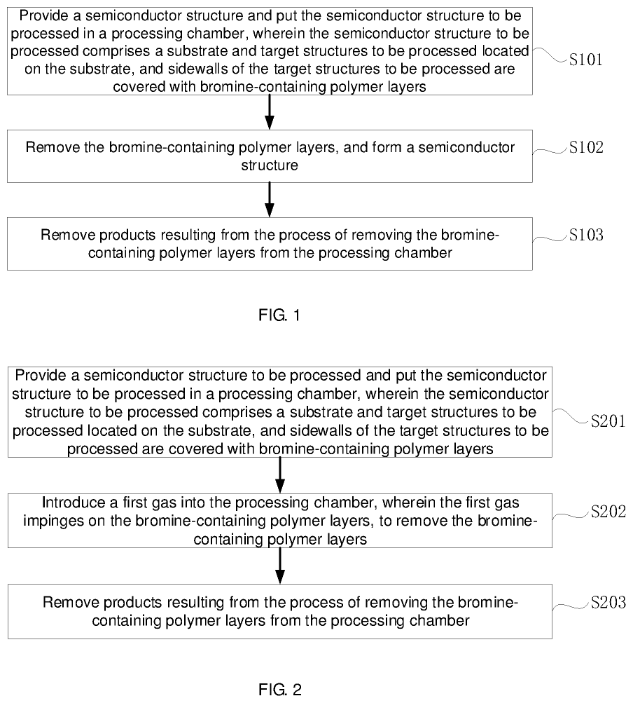

As shown in FIG. 2, a method of manufacturing a semiconductor structure provided according to some embodiments of the present disclosure comprises S201 to S203.

In the S201, a semiconductor structure to be processed is provided and put the semiconductor structure to be processed in a processing chamber. The semiconductor structure to be processed comprises a substrate and target structures to be processed located on the substrate, and sidewalls of the target structures to be processed are covered with bromine-containing polymer layers.

In the S202, a first gas is introduced into the processing chamber, wherein the first gas impinges on the bromine-containing polymer layers, to remove the bromine-containing polymer layers.

In the S203, products resulting from the process of removing the bromine-containing polymer layers are removed from processing chamber.

In this embodiment, the S201 and the S203 are implemented in the same manner as that in the above embodiment and will not be repeated herein.

In the S202 of this embodiment, as shown in FIG. 7, a first gas is introduced into the processing chamber 10 (see FIG. 12) by a dry etching process, and then ionized in the processing chamber 10. After being accelerated by an electric field in the processing chamber 10, ions of the first gas impinges on the bromine-containing polymer layers 210 to separate the bromine-containing polymers from the target structures to be processed 200. For example, when the first gas is argon, a High source power is applied to generate more argon plasma in the chamber, and a Low Bias power is applied to cause argon ions to impinge on the bromine-containing polymer layers 210 at an appropriate rate, so as to reduce the damage of argon ions to the substrate 100, and the bromine-containing polymers are separated from the target structures to be processed 200 by causing the argon ions to impinge on the bromine-containing polymer layers 210. The first gas may also be helium.

Argon ions or helium ions impinge on the bromine-containing polymer layers 210 vertically downward to remove the bromine-containing polymers.

The products are products after solid bromine-containing polymers are separated from the sidewalls of the targets to be processed in a molecular state under the impingement of argon ions or helium ions, and are pumped out of the processing chamber 10 by a vacuum pump, thus removing the bromine-containing polymers from the processing chamber 10, removing bromine more completely in the manufacturing process of the semiconductor structure, reducing the probability of defects of HBr concentration and improving the yield of semiconductor devices.

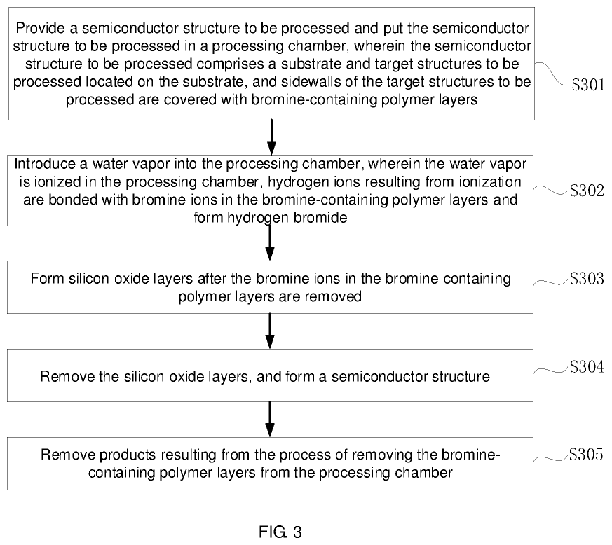

As shown in FIG. 3, a method of manufacturing a semiconductor structure provided according to some embodiments of the present disclosure comprises S301 to S305.

In the S301, a semiconductor structure to be processed is provided and put the semiconductor structure to be processed in a processing chamber. The semiconductor structure to be processed comprises a substrate and target structures to be processed located on the substrate, and sidewalls of the target structures to be processed are covered with bromine-containing polymer layers.

In the S302, a water vapor is introduced into the processing chamber, wherein the water vapor is ionized in the processing chamber, and hydrogen ions resulting from ionization are bonded with bromine ions in the bromine-containing polymer layers, and form hydrogen bromide.

In the S303, form silicon oxide layers after the bromine ions in the bromine-containing polymer layers are removed.

In the S304, the silicon oxide layers are removed, and form a semiconductor structure.

In the S305, products resulting from the process of removing the bromine-containing polymer layers are removed from processing chamber.

In this embodiment, the S301 and the S305 are implemented in the same manner as that in the above embodiments and will not be repeated herein.

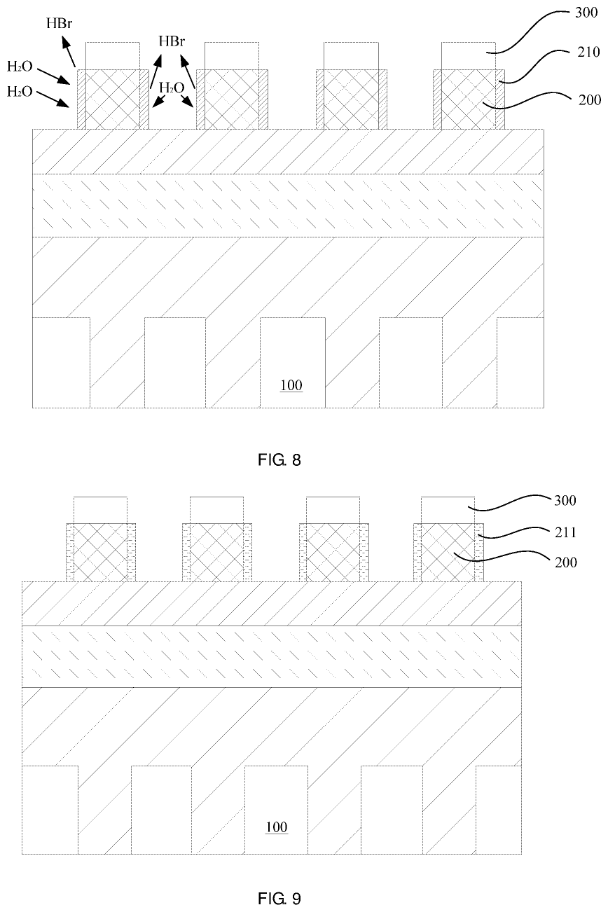

In the S302 and the S303, as shown in FIGS. 8 and 9, after being introduced into the processing chamber 10 (see FIG. 12), the water vapor is ionized into hydrogen ions and oxygen ions under an electric field in the processing chamber 10, and the hydrogen ions and oxygen ions undergo oxidation reaction with the bromine-containing silicon oxide (SiₓO_{y}Br_{z}) in the bromine-containing polymer layers 210 to generate silicon oxide SiₓO_{w} and hydrogen bromide (HBr). After the bromine ions in the bromine-containing polymer layers 210 are removed, the silicon oxide layers 211 are formed on the sidewalls of the target structures to be processed 200, so that bromine can be separated from the bromine-containing polymer layers 210. At this moment, the generated HBr can be directly pumped out of the processing chamber 10 by a vacuum pump, thereby removing the bromine ions in the bromine-containing polymer layers 210, avoiding the bromine-containing polymer layers 210 from generating HBr in the processing chamber 10, removing bromine from the processing chamber 10 more completely, reducing the probability of defects of HBr concentration and improving the yield of semiconductor devices.

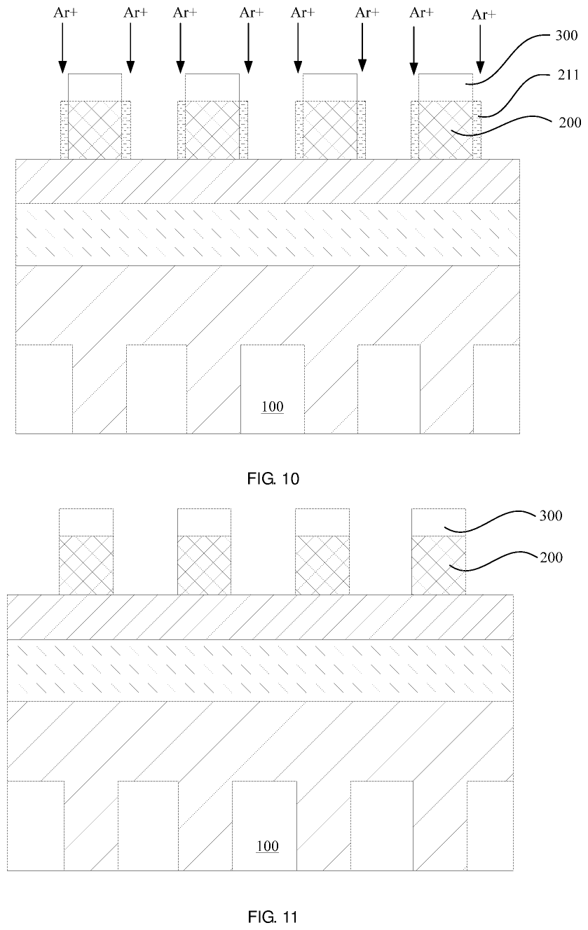

In the S304, as shown in FIGS. 10 and 11, the silicon oxide layers 211 are removed to completely expose the sidewalls of the target structures to be processed 200, so as to avoid the silicon oxide layers 211 having a large dielectric constant from being coated on the sidewalls of the target structures to be processed 200, and to improve the conductive characteristics of the target structure to be processed 200.

The S304 in which the silicon oxide layers 211 are removed and form a semiconductor structure comprises a introducing a second gas into the processing chamber 10 (see FIG. 12) wherein the second gas impinges on the silicon oxide layers 211, to remove the silicon oxide layers 211. The second gas is introduced into the processing chamber 10 by a dry etching process, and then ionized in the processing chamber 10. After being accelerated by an electric field in the processing chamber 10, ions of the second gas impinges on the silicon oxide layers 211, so that the silicon oxide is separated from the target structure to be processed 200, resulting in products. The second gas is argon or helium. The products are products after the solid silicon oxide is separated from the sidewalls of the targets to be processed in a molecular state under the impingement of argon ions, and are pumped out of the processing chamber 10 by the vacuum pump, thus removing contaminants from the processing chamber 10.

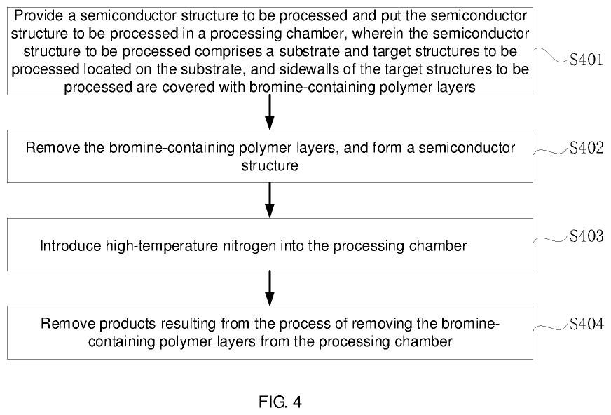

As shown in FIG. 4, a method of manufacturing a semiconductor structure provided according to an exemplary embodiment of the present disclosure comprises S401 to S404.

In the S401, a semiconductor structure to be processed is provided and put the semiconductor structure to be processed in a processing chamber. The semiconductor structure to be processed comprises a substrate and target structures to be processed located on the substrate, and sidewalls of the target structures to be processed are covered with bromine-containing polymer layers.

In the S402, the bromine-containing polymer layers are removed, and form a semiconductor structure.

In the S403, high-temperature nitrogen is introduced into the processing chamber.

In the S404, products resulting from the process of removing the bromine-containing polymer layers are removed from processing chamber.

In this embodiment, the S401, the S402 and the S404 are implemented in the same manner as that in the above embodiments and will not be repeated herein.

In the S403, the high-temperature nitrogen is introduced into the processing chamber. On the one hand, nitrogen can serve as a protective gas. After being introduced into the processing chamber 10, nitrogen can dilute contaminants in the processing chamber 10, protect the semiconductor structure, and reduce the probability of the semiconductor structure reacting with oxygen and other gases in the processing chamber 10. For example, polysilicon readily reacts with oxygen to produce silicon oxide. On the other hand, the high-temperature nitrogen can promote the gasification of residual HBr, and avoid the condensation of HBr on the surfaces of the semiconductor structure, so that HBr can be more easily pumped out together with nitrogen by a vacuum pump to remove bromine more completely.

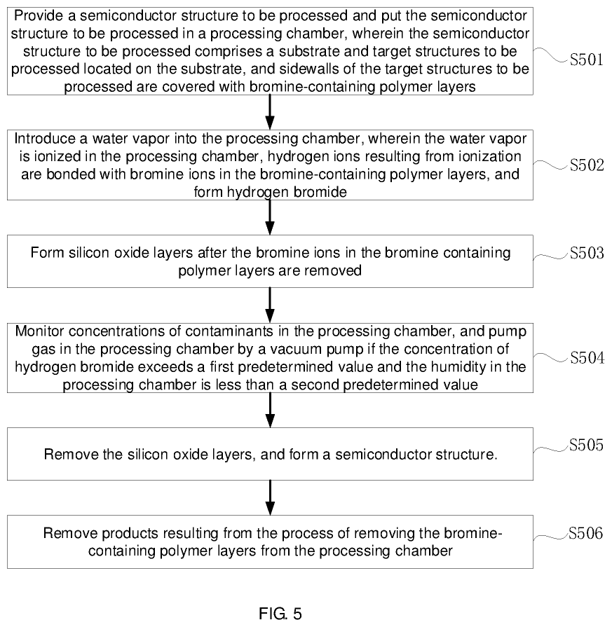

As shown in FIG. 5, a method of manufacturing a semiconductor structure provided according to some embodiments of the present disclosure comprises S501 to S506.

In the S501, a semiconductor structure to be processed is provided and put the semiconductor structure to be processed in a processing chamber. The semiconductor structure to be processed comprises a substrate and target structures to be processed located on the substrate, and sidewalls of the target structures to be processed are covered with bromine-containing polymer layers.

In the S502, water vapor is introduced into the processing chamber, wherein the water vapor is ionized in the processing chamber, and hydrogen ions resulting from ionization are bonded with bromine ions in the bromine-containing polymer layers, and form hydrogen bromide.

In the S503, form silicon oxide layers after the bromine ions in the bromine-containing polymer layers are removed.

In the S504, concentrations of contaminants in the processing chamber is monitored, and gas in the processing chamber is pumped by a vacuum pump if the concentration of hydrogen bromide exceeds a first predetermined value and the humidity in the processing chamber is less than a second predetermined value.

In the S505, the silicon oxide layers are removed, and form a semiconductor structure.

In the S506, products resulting from the process of removing the bromine-containing polymer layers are removed from processing chamber.

In this embodiment, the S501 to S503, the S505 and the S506 are implemented in the same manner as that in the above embodiments and will not be repeated herein.

In the S504, as shown in FIGS. 14, 15 and 16, after being introduced into the processing chamber 10 (see FIG. 12), the water vapor is continuously consumed to produce hydrogen bromide (HBr) constantly, with the concentration of the water vapor in the processing chamber 10 gradually decreasing and the concentration of hydrogen bromide gradually increasing. If the concentration of hydrogen bromide exceeds the first predetermined value and the humidity of the processing chamber 10 is less than the second predetermined value, it indicates that all or most of the bromine-containing polymer layers 210 on the semiconductor structure to be processed are oxidized by water vapor. At this moment, the gas in the processing chamber 10 is pumped by the vacuum pump to remove water vapor, HBr and other contaminants in the processing chamber 10, thus achieving bromine removal.

The first predetermined value and the second predetermined value may be specific values or change rates. For example, the first predetermined value is set to a zero growth rate. When the growth rate is zero, it indicates that the bromine-containing polymer has completely reacted and no longer produces hydrogen bromide. At this moment, the concentration of hydrogen bromide is at its maximum, and then the hydrogen bromide is pumped out of the processing chamber by the vacuum pump.

As shown in FIG. 14, in one embodiment of the present disclosure, a process flow of the semiconductor structure to be processed mainly comprises five steps, i.e., A: film deposition; B: photoetching (PH, PHOTO); C: etching (ETCH); D: wet cleaning (WET, dust, metal ions and organic impurities remaining on the wafer are removed with a chemical solution); and E: rinsing the substrate with deionized water. The S504 is specifically provided after the etching (ETCH) process and before the wet cleaning process. As shown in FIGS. 15 and 16, after water vapor is introduced, the concentration of water vapor in the processing chamber 10 gradually decreases and the concentration of hydrogen bromide gradually increases. In the step D, the humidity reaches its minimum and the concentration of HBr gradually reaches its maximum. At this moment, the HBr is pumped out by the vacuum pump to gradually reduce the concentration of hydrogen bromide until the HBr in the processing chamber is completely removed. Then, the S505 and the S506 are performed to completely remove the bromine-containing polymers on the semiconductor structure to be processed, and to pump the bromine-containing substances out of the processing chamber 10, thus removing bromine more completely, avoiding the residual bromine-containing polymers in the semiconductor structure to be processed or in the processing chamber 10 from regenerating HBr, and reducing the probability of condensation of HBr on the semiconductor structure to be processed and therefore contributing to the improvement of the yield of the semiconductor structure.

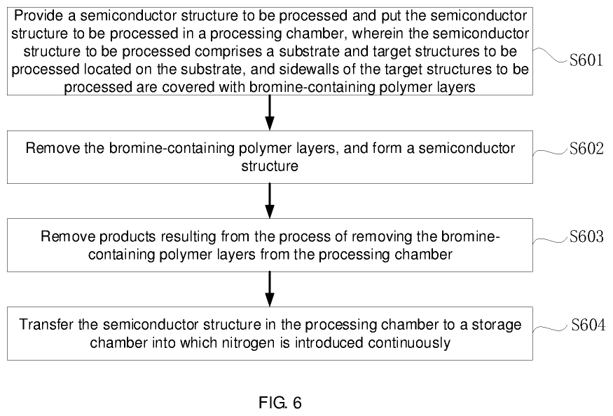

As shown in FIG. 6, a method of manufacturing a semiconductor structure provided according to an exemplary embodiment of the present disclosure comprises S601 to S604.

In the S601, a semiconductor structure to be processed is provided and put the semiconductor structure to be processed in a processing chamber. The semiconductor structure to be processed comprises a substrate and target structures to be processed located on the substrate, and sidewalls of the target structures to be processed are covered with bromine-containing polymer layers.

In the S602, the bromine-containing polymer layers are removed, and form a semiconductor structure.

In the S603, products resulting from the process of removing the bromine-containing polymer layers are removed from processing chamber.

In the S604, the semiconductor structure in the processing chamber is transferred to a storage chamber. The storage chamber into which nitrogen is introduced is communicated with the processing chamber continuously.

In this embodiment, the S601 to S603 are implemented in the same manner as that in the above embodiments and will not be repeated herein.

As shown in FIG. 11, referring to FIG. 7, after the bromine-containing polymer layers 210 are removed, the sidewalls of the target structures to be processed 200 are completely exposed. In this embodiment, the target structure to be processed 200 is a Landing Pad made of silicon, and silicon readily reacts with other gases in the processing chamber 10 (see FIG. 12) under an electric field and form silicon compounds (such as SiO2). Therefore, in the S604, the semiconductor structure in the processing chamber 10 is transferred to a storage chamber for storage, and nitrogen is introduced into the storage chamber continuously. On the one hand, the semiconductor structure is removed from the electric field in the processing chamber 10. On the other hand, nitrogen is introduced into the storage chamber continuously to dilute contaminants that may present in the storage chamber, and inert gas protects the semiconductor structure from contact with other contaminants, thus protecting all portions of the semiconductor structure, avoiding the generation of oxide layers on the sidewalls of the target structures to be processed 200, and improving the conductive characteristics of the target structures to be processed 200.

As shown in FIG. 12, according to a second aspect of the present disclosure, a semiconductor device etching equipment is provided, for implementing the method of manufacturing a semiconductor structure in the technical solutions of the first aspect. The equipment comprises at least one processing chamber 10, at least one processing device, and at least one cleaning device. Each processing chamber 10 is communicated with the processing device and the cleaning device respectively, the processing chamber 10 is an etching chamber, configured to hold a semiconductor structure to be processed and performing etching, cleaning and other processes on the semiconductor structure to be processed. The processing device can remove bromine-containing polymer layers 210, and each cleaning device is a vacuum pump by which products resulting from the process of removing the bromine-containing polymer layers 210 are pumped out to completely remove bromine-containing substances from the processing chamber 10.

In an exemplary embodiment of the present disclosure, each processing device comprises a first gas storage device communicated with the processing chamber 10 to supply a first gas to the processing chamber 10 through the processing device. The first gas is ionized into ions under an electric field in the processing chamber 10 to impinge on the bromine-containing polymer layers 210, so that the bromine-containing polymer layers 210 are separated from the target structures to be processed 200. The first gas is argon or helium.

In another exemplary embodiment of the present disclosure, each processing device comprises a water vapor generator and a second gas storage device, both of which are communicated with the processing chamber 10. The water vapor generator is configured to introduce water vapor into the processing chamber 10, and the water vapor is ionized into hydrogen ions and oxygen ions under the electric field in the processing chamber 10. The hydrogen ions and oxygen ions react with bromine-containing polymers to generate hydrogen bromide HBr and silicon oxide (referring to FIG. 9) and form silicon oxide layers 211 on sidewalls of the target structures to be processed 200, and the generated hydrogen bromide HBr is pumped out of the processing chamber 10 by a vacuum pump to remove bromine. The second gas storage device introduces a second gas into the processing chamber 10, and the second gas is ionized into ions under the electric field in the processing chamber 10 to impinge on the silicon oxide layers 211, so that the silicon oxide layers 211 are separated from the target structures to be processed 200. The second gas is argon or helium.

According to some embodiments of the present disclosure, as shown in FIG. 12, the equipment further comprises a transfer chamber 20, a buffer chamber 30, first storage chambers 40 and second storage chambers 50. The transfer chamber 20 is communicated with the processing chamber 10, the buffer chamber 30 is communicated with the transfer chamber 20, the first storage chambers 40 and the second storage chambers 50 are communicated with the buffer chamber 30, so that the processing chamber 10, the transfer chamber 20, the buffer chamber 30, the first storage chambers 40, and the second storage chambers 50 are communicated and closed as a whole. The first storage chambers 40 are mainly configured to store the semiconductor structures to be processed, the second storage chambers 50 are configured to store the processed semiconductor structures, and the buffer chamber 30 serves as an area for temporarily holding the semiconductor structure to be processed in the processing chamber 10, so that the semiconductor structure to be processed can be stored during the semiconductor structure to be processed is processed in the processing chamber 10, which shortens the time for transferring the next semiconductor structure to be processed to the processing chamber 10 after the previous one has been processed and thus improves the processing efficiency.

A first robot arm 70, which is configured to transfer semiconductor structures between the transfer chamber 20 and the processing chamber 10 and the buffer chamber 30, is disposed in the transfer chamber 20, and a second robot arm 80, which is configured to transfer semiconductor structures between the buffer chamber 30 and the first storage chambers 40, the second storage chambers 50 and the transfer chamber 20, is disposed in the buffer chamber 30. The first robot arm 70 and the second robot arm 80 work together to transfer the semiconductor structures to be processed in the first storage chambers 40 to the processing chamber 10, and then transfer the formed semiconductor structures from the processing chamber 10 to the second storage chambers 50 after the manufacturing process of the semiconductor structure to be processed is completed.

There may be one or more processing chambers 10. In an exemplary embodiment, as shown in FIG. 12, there are five processing chambers 10 respectively disposed around the transfer chamber 20, so that semiconductor structures to be processed may be processed at the same time to improve processing efficiency.

As shown in FIG. 13, according to some embodiments of the present disclosure, the semiconductor device etching equipment further comprises a protective gas storage device 60 which is communicated with the second storage chamber 50 and the processing chamber 10 respectively and configured to introduce nitrogen into the second storage chamber 50 or the processing chamber 10 continuously. The protective gas storage device 60 is configured to introduce nitrogen into the second storage chamber 50 continuously to dilute possible contaminants that may present in the second storage chamber 50, and inert gas protects the semiconductor structure from contact with other contaminants, thus protecting all portions of the semiconductor structure, avoiding the generation of oxide layers on the sidewalls of the target structures to be processed 200, and improving the conductive characteristics of the target structure to be processed 200. The protective gas storage device 60 is configured to introduce nitrogen into the processing chamber 10 continuously to promote gasification of HBr remaining on the semiconductor structure, and avoid condensation of HBr on the surfaces of the semiconductor structure, so that HBr can be more easily pumped out together with nitrogen by a vacuum pump to remove HBr more completely.

The protective gas storage device 60 is provided with a gas delivery pipe 61 and a gas return pipe 62, which are respectively communicated with the second storage chamber 50. The gas delivery pipe 61 is configured to deliver nitrogen into the second storage chamber 50, and the gas return pipe 62 is configured to discharge mixed gas of nitrogen and other gases in the storage chambers, so that the protective gas storage device 60 can introduce nitrogen into the second storage chamber 50 continuously. A purification pipe 611, a manual valve 612, a pressure gage 613, a pneumatic valve 614 and a gas flow controller are provided in sequence on the gas delivery pipe 61 in the flow direction of nitrogen. The purification pipe 611 is configured to filter contaminants such as water vapor and impurities to ensure that pure nitrogen is input into the second storage chamber 50. The manual valve 612 and the pneumatic valve 614 are configured to open or close the gas delivery pipe 61. The pressure gage 613 can display nitrogen pressure in the delivery pipe. A gas flow control valve 615 is configured to control the flow rate of nitrogen introduced into the second storage chamber 50.

According to some embodiments of the present disclosure, the semiconductor device etching equipment further comprises a detection device, configured to detect the concentration of at least one gaseous substance in the processing chamber 10, such as the concentration of hydrogen bromide and water vapor. The detection device comprises at least one gas analyzer communicated with the interior of the processing chamber 10 through a pipe to analyze gaseous substances in the processing chamber 10.

Depending on the type and quantity of gaseous substances to be detected, there may be one, two or more gas analyzers to detect the concentration of different gaseous substances in the processing chamber 10, respectively, such as the concentration of hydrogen bromide, water vapor and oxygen.

In the semiconductor structure manufacturing method and the semiconductor device etching equipment provided in the embodiments of the present disclosure, the bromine-containing polymer layers are removed from the semiconductor structure to be processed and from the processing chamber to avoid the bromine-containing polymer from generating HBr in the processing chamber, so that bromine is removed from the processing chamber more completely, the probability of HBr condensation on the semiconductor structure is reduced, and the yield of the semiconductor structure is improved. In this specification, each embodiment or implementation way is described in a progressive manner, and each embodiment focuses on the differences from other embodiments, so it is sufficient to refer to the same and similar content of all embodiments.

In the description of this specification, references to such terms as “embodiment”, “exemplary embodiment”, “some embodiments”, “schematic embodiment” and “example” mean that the specific features, structures, materials or characteristics described based on the implementation way or example are included in at least one embodiment or example of the present disclosure.

In this specification, the schematic expressions of the above terms do not necessarily refer to the same embodiments or examples. Furthermore, the specific features, structures, materials or characteristics described may be combined in an appropriate manner in any one or more embodiments or examples.

In the description of the present disclosure, it should be understood that the positions or positional relationship indicated by the terms “center”, “upper”, “lower”, “left”, “right”, “vertical”, “horizontal”, “inner” and “outer” and the like are positions or positional relationship as shown in the drawings, which are not used for indicating or implying that the devices or elements must have specific positions and be construed and operated by the specific positions, but merely for facilitating and simplifying the description of the present disclosure. Therefore, it should not be construed as limiting the present invention.

It will be understood that the terms “first”, “second” and the like used in the present disclosure may be used for describing various structures in the present disclosure, but these structures are not limited by these terms. These terms are merely used for distinguishing one structure from another.

In one or more drawings, the same elements are denoted by similar reference numerals. For clarity, several components in the drawings are not drawn to scale. In addition, certain well-known components may not be shown. For simplicity, the structure obtained after several steps may be illustrated in one figure. Many particular details of the present disclosure, such as device construction, materials, dimensions, processing and techniques, are described below for a clearer understanding of the present disclosure. However, as will be understood by those of skill in the art, the present disclosure may be implemented without these specific details.

Finally, it should be noted that the above embodiments are not used for limiting but merely for describing the technical solutions of the present disclosure. Although the present disclosure has been described in detail with reference to the above embodiments, those of skill in the art should understand that it is still possible to modify the technical solutions described in the above embodiments, or to substitute some or all of the technical features with equivalents. However, such modifications or substitutions do not make the essence of the corresponding technical solutions deviate from the scope of the technical solutions in the embodiments of the present disclosure.

### INDUSTRIAL APPLICABILITY

In the method of manufacturing a semiconductor structure and the semiconductor device etching equipment provided in the embodiments of the present disclosure, the bromine-containing polymer layers are removed from the semiconductor structure to be processed and from the processing chamber to avoid the bromine-containing polymer from generating HBr in the processing chamber, so that bromine is removed from the processing chamber more completely, the probability of HBr condensation on the semiconductor structure is reduced, and the yield of the semiconductor structure is improved.

1. A method of manufacturing a semiconductor structure, comprising:
providing a semiconductor structure to be processed, putting the semiconductor structure to be processed in a processing chamber, wherein the semiconductor structure to be processed comprises a substrate and target structures to be processed located on the substrate, and sidewalls of the target structures to be processed are covered with bromine-containing polymer layers;
removing the bromine-containing polymer layers, and forming a semiconductor structure; and
removing products resulting from a process of removing the bromine-containing polymer layers from the processing chamber.

2. The method of manufacturing a semiconductor structure according to claim 1, wherein the removing the bromine-containing polymer layers, and forming a semiconductor structure comprises:
introducing a first gas into the processing chamber, wherein the first gas impinges on the bromine-containing polymer layers, to remove the bromine-containing polymer layers.

3. The method of manufacturing a semiconductor structure according to claim 1, wherein the removing the bromine-containing polymer layers, and forming a semiconductor structure comprises:
introducing a water vapor into the processing chamber, wherein the water vapor is ionized in the processing chamber, hydrogen ions resulting from ionization are bonded with bromine ions in the bromine-containing polymer layers, and forming hydrogen bromide;
forming silicon oxide layers after the bromine ions in the bromine-containing polymer layers are removed; and
removing the silicon oxide layers, and forming the semiconductor structure.

4. The method of manufacturing a semiconductor structure according to claim 3, wherein the forming silicon oxide layers after the bromine ions in the bromine-containing polymer layers are removed comprises:
introducing a second gas into the processing chamber, wherein the second gas impinges on the silicon oxide layers, to remove the silicon oxide layers.

5. The method of manufacturing a semiconductor structure according to claim 3, wherein after the forming silicon oxide layers after the bromine ions in the bromine-containing polymer layers are removed, further comprises:
monitoring concentrations of contaminants in the processing chamber, and pumping gas in the processing chamber by a vacuum pump if a concentration of the hydrogen bromide exceeds a first predetermined value and a humidity in the processing chamber is less than a second predetermined value.

6. The method of manufacturing a semiconductor structure according to claim 1, before the removing products resulting from a process of removing the bromine-containing polymer layers from the processing chamber, further comprises:
introducing high-temperature nitrogen into the processing chamber.

7. The method of manufacturing a semiconductor structure according to claim 1, wherein the removing products resulting from a process of removing the bromine-containing polymer layers from the processing chamber comprises:
pumping the products out of the processing chamber by a vacuum pump.

8. The method of manufacturing a semiconductor structure according to claim 1, after the removing products resulting from a process of removing the bromine-containing polymer layers from the processing chamber, further comprises:
transferring the semiconductor structure in the processing chamber to a storage chamber, wherein the storage chamber is communicated with the processing chamber, and introducing nitrogen into the storage chamber continuously.

9. A semiconductor device etching equipment, for implementing the method of manufacturing a semiconductor structure according to claim 1, comprising:
at least one processing chamber, each configured to hold a semiconductor structure to be processed;
at least one processing device, each configured to remove bromine-containing polymer layers; and
at least one cleaning device, each configured to be communicated with the processing chamber, and clean products resulting from a process of removing the bromine-containing polymer layers.

10. The semiconductor device etching equipment according to claim 9, wherein the processing device comprises a first gas storage device, the first gas storage device is communicated with the processing chamber.

11. The semiconductor device etching equipment according to claim 9, wherein the processing device comprises:
a water vapor generation device, the water vapor generation device being communicated with the processing chamber; and
a second gas storage device, the second gas storage device being communicated with the processing chamber.

12. The semiconductor device etching equipment according to claim 9, further comprising:
a transfer chamber, communicated with the processing chamber;
a buffer chamber, communicated with the transfer chamber;
first storage chambers and second storage chambers, communicated with the buffer chamber; and
a first robot arm being disposed in the transfer chamber, a second robot arm being disposed in the buffer chamber, and the first robot arm and the second robot arm being configured to transfer the semiconductor structures to be processed in the first storage chambers to the processing chamber, or transfer semiconductor structures from the processing chamber to the second storage chambers.

13. The semiconductor device etching equipment according to claim 12, further comprising:
a protective gas storage device, communicated with the second storage chambers and the processing chamber respectively, and the protective gas storage device is configured to introduce nitrogen into at least one of the second storage chambers or the processing chamber continuously.

14. The semiconductor device etching equipment according to claim 11, further comprising:
a detection device, configured to detect a concentration of at least one gaseous substance in the processing chamber.

15. The semiconductor device etching equipment according to claim 14, wherein the detection device comprises at least one gas analyzer, the at least one gas analyzer being communicated with interior of the processing chamber.
